(19) United States
(12) Patent Application Publication
(10) Pub. No.: US 2026/0323907 A1
(43) Pub. Date: Oct. 15, 2026

(54) SEMICONDUCTOR STRUCTURE AND METHOD OF MANUFACTURING THE SAME

(71) Applicant: NANYA TECHNOLOGY CORPORATION, NEW TAIPEI CITY (TW)

(72) Inventors: SHIH-TING HUANG, NEW TAIPEI CITY (TW); TSUNG-CHIN HSU, NEW TAIPEI CITY (TW)

(21) Appl. No.: 19/335,215

(22) Filed: Sep. 22, 2025

Related U.S. Application Data
(63) Continuation of application No. 19/179,884, filed on Apr. 15, 2025.

(51) Int. Cl. H10B 12/00

(52) U.S. Cl. CPC H10B 12/033; H10B 12/315

(57) ABSTRACT

The present application provides a semiconductor structure including a substrate, a dielectric stack disposed on the substrate, and a hard mask layer disposed on the dielectric stack. The semiconductor structure further includes an aluminum-containing conductive layer surrounding the hard mask layer and the dielectric stack and over the hard mask layer from a cross-section view, wherein the aluminum-containing conductive layer is conformal to the hard mask layer and the dielectric stack; and a first oxide layer disposed over and conformal to the aluminum-containing conductive layer.

### CROSS-REFERENCE TO RELATED APPLICATION

This application is a continuation application of U.S. Non-Provisional application Ser. No. 19/179,884 filed Apr. 15, 2025, which is incorporated herein by reference in its entirety.

### TECHNICAL FIELD

The present disclosure relates to a semiconductor structure, and a method of manufacturing the semiconductor structure. Particularly, the present disclosure relates to a semiconductor structure having an aluminum-containing conductive layer, and a method of manufacturing the semiconductor structure including forming the aluminum-containing conductive layer.

### DISCUSSION OF THE BACKGROUND

Semiconductor devices are used in a variety of electronic applications, such as personal computers, cellular telephones, digital cameras, and other electronic equipment, and capacitors are used in a wide variety of semiconductor circuits. For example, the capacitors are used in dynamic random-access memory (DRAM) memory circuits and other types of memory circuits. DRAM memory circuits are manufactured by replicating millions of identical circuit elements, known as DRAM cells, on a single semiconductor wafer. A DRAM cell is an addressable location that can store one bit (binary digit) of data. In its most common form, a DRAM cell consists of two circuit components, a storage capacitor and an access field-effect transistor.

Memory devices are getting smaller and smaller in physical size with each generation. During manufacture of memory cells, an existing process is prone to deficiencies due to such reduction of critical dimensions. This is because the process used in manufacturing the memory cell often over-etches an upper electrode plate used to deposit a capacitor and a dielectric layer.

In some semiconductor manufacturing processes, when a hard mask is etched by an etching gas, a short circuit may occur between capacitors. Therefore, it is necessary to protect a lower electrode plate during a chemical mechanical polishing (CMP) process and prevent a chemical polishing slurry from falling into an opening between the capacitors. However, a structure configured to protect the lower electrode plate needs to be removed later, and the lower electrode plate may be damaged during the removal.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes a substrate, a dielectric stack disposed on the substrate, and a hard mask layer disposed on the dielectric stack. The semiconductor structure further includes an aluminum-containing conductive layer surrounding the hard mask layer and the dielectric stack and over the hard mask layer from a cross-section view, wherein the aluminum-containing conductive layer is conformal to the hard mask layer and the dielectric stack; and a first oxide layer disposed over and conformal to the aluminum-containing conductive layer.

Another aspect of the present disclosure provides a semiconductor structure. The semiconductor structure includes a substrate having an active region, a first column disposed on the active region, a second column disposed on the active region and adjacent to the first column, and an aluminum-containing conductive layer continuously disposed over and surrounding the first column and the second column. The aluminum-containing conductive layer is conformal to the first column and the second column.

Another aspect of the present disclosure provides a method of manufacturing a semiconductor structure. The method includes steps of providing a substrate having an active region, wherein the active region includes an isolation structure and a contact adjacent to the isolation structure; forming a dielectric stack on the substrate; forming a hard mask layer on the dielectric stack; and etching the hard mask layer and the dielectric stack to form an opening to expose the contact of the substrate. The method further includes steps of forming a conductive film within the opening and over the hard mask layer, wherein the conductive film is conformal to the opening; modifying the conductive film to turn the conductive film into an aluminum-containing conductive layer; and depositing a first oxide layer over the aluminum-containing conductive layer, wherein the first oxide layer is conformal to the aluminum-containing conductive layer.

As a result, a top portion of the opening is sealed by the first oxide layer to form a space and protect a lower electrode plate in a chemical-mechanical polishing (CMP) process, wherein the CMP slurry can be prevented from falling into the openings between the capacitors. Further, due to an improved material of the aluminum-containing conductive layer, the aluminum-containing conductive layer serves as the lower electrode plate that is not easily oxidized by the first oxide layer, and the aluminum-containing conductive layer can remain in place after the first oxide layer is removed. In conclusion, the lower electrode plate will not be substantially damaged when the first oxide layer is removed, improving quality and reliability of the semiconductor structure.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRA WINGS

A more complete understanding of the present disclosure may be derived by referring to the detailed description and claims. The disclosure should also be understood to be coupled to the figures' reference numbers, which refer to similar elements throughout the description.

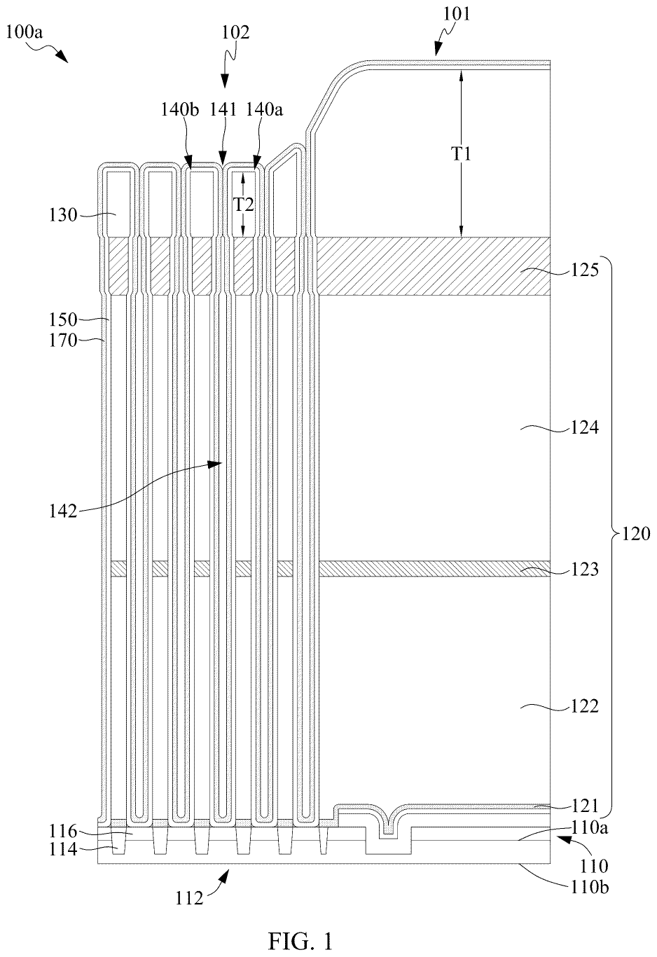

FIG. 1 is a cross-sectional view of a first semiconductor structure in accordance with some embodiments of the present disclosure.

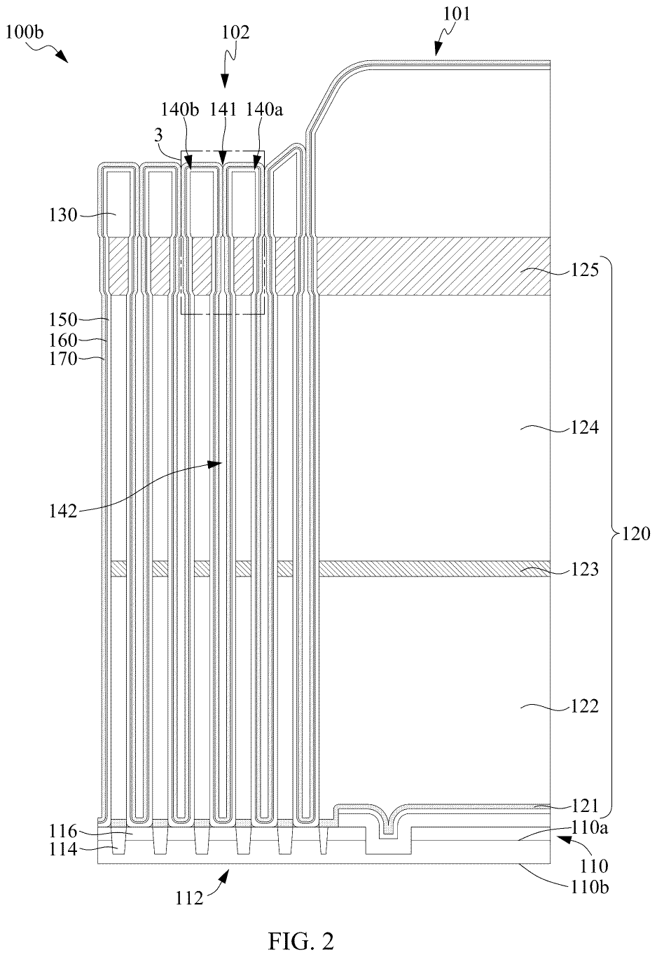

FIG. 2 is a cross-sectional view of a second semiconductor structure in accordance with some embodiments of the present disclosure.

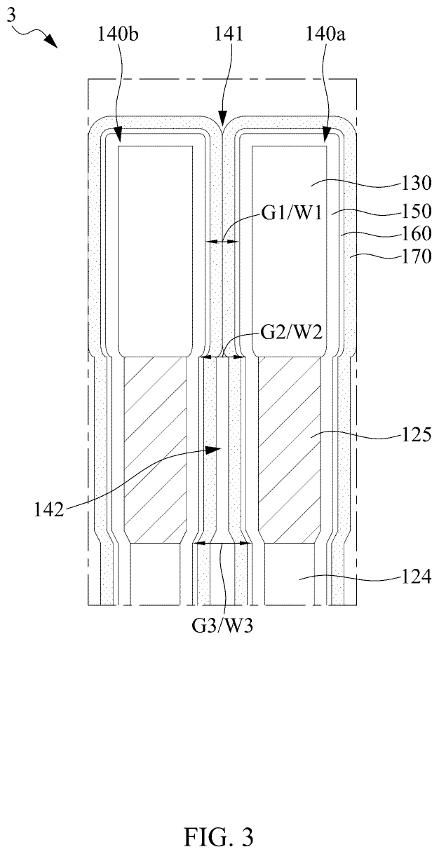

FIG. 3 is an enlarged cross-sectional view of a part of the second semiconductor structure in FIG. 2 in accordance with some embodiments of the present disclosure.

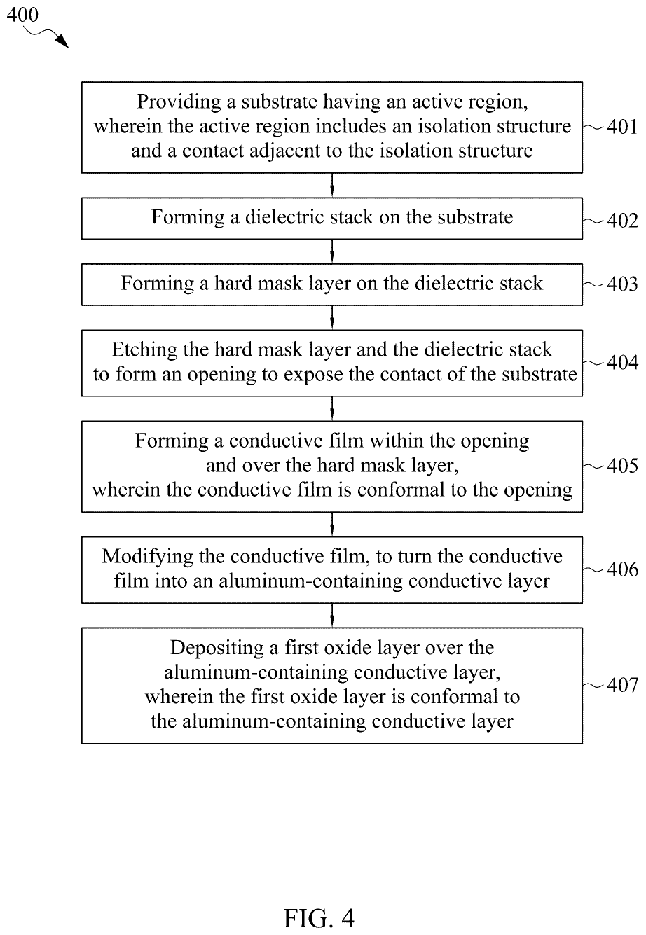

FIG. 4 is a flow diagram illustrating a method of manufacturing a semiconductor structure in accordance with some embodiments of the present disclosure.

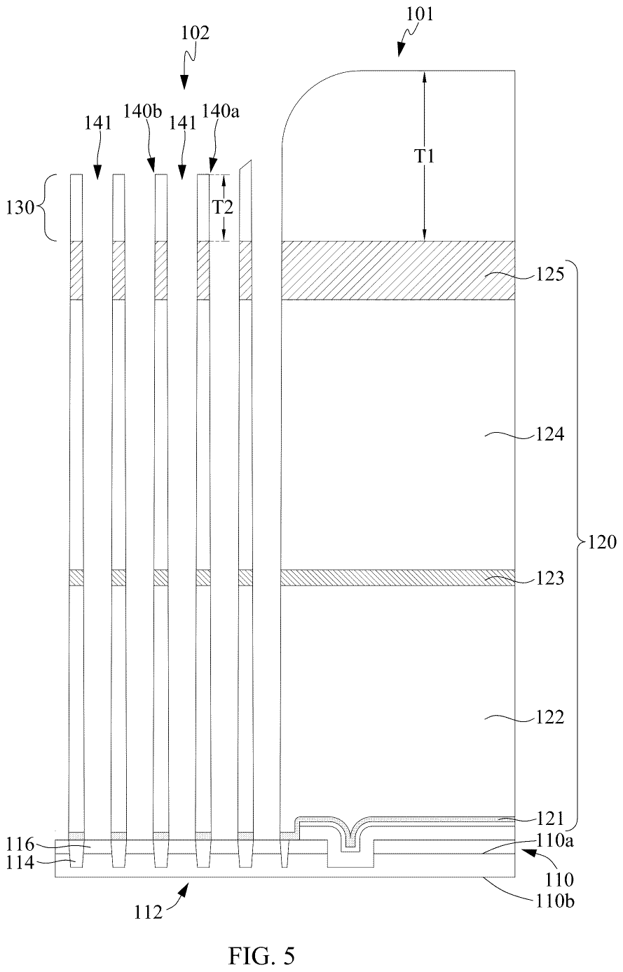

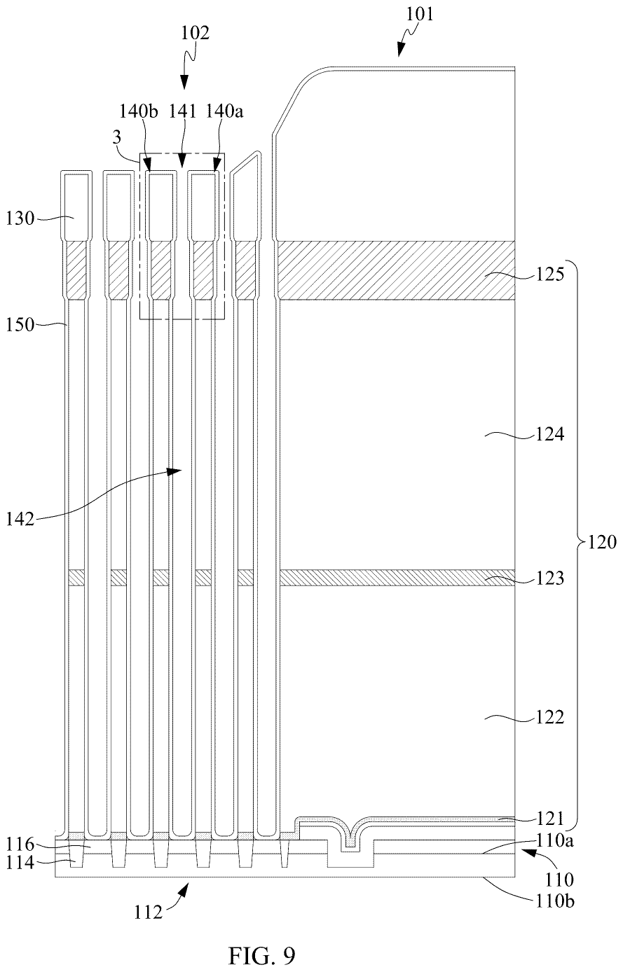

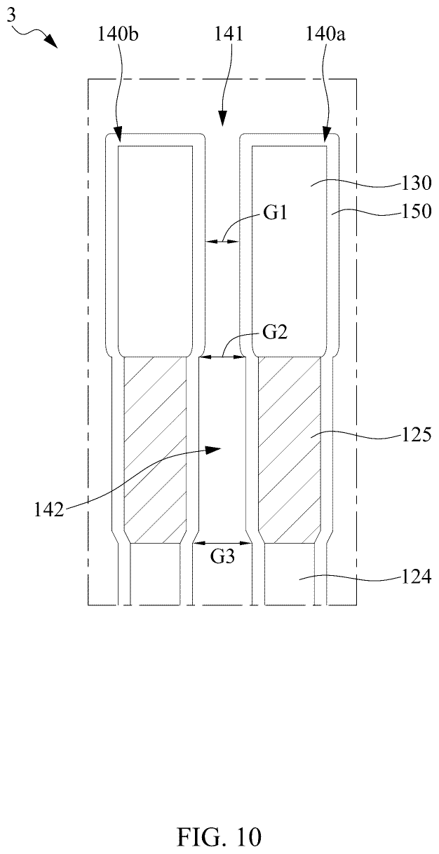

FIGS. 5 to 7, 9 to 10, 15 to 17 and 19 are cross-sectional views of intermediate stages in the formation of a semiconductor structure in accordance with some embodiments of the present disclosure.

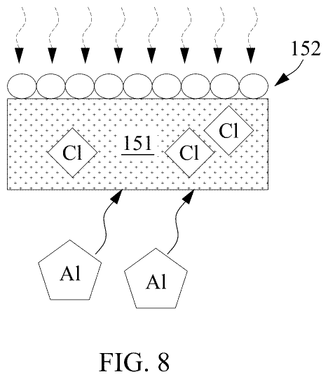

FIGS. 8, 11 to 14 and 18 are schematic views of intermediate stages in the formation of a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 is a schematic cross-sectional view of a first semiconductor structure 100a in accordance with some embodiments of the present disclosure. In some embodiments, the first semiconductor structure 100a is a part of a die, a package or a device. In some embodiments, the first semiconductor structure 100a is a die, a package or a device. In some embodiments, the first semiconductor structure 100a includes a capacitor.

In some embodiments, the first semiconductor structure 100a includes a substrate 110, a dielectric stack 120 disposed on the substrate 110, a hard mask layer 130 disposed on the dielectric stack 120, and a space 142 surrounded by the hard mask layer 130 and the dielectric stack 120 to define a first column 140a and a second column 140b. In some embodiments, a top surface of each of the first column 140a and the second column 140b has a circular, quadrilateral or polygonal shape. The first semiconductor structure 100a further includes an aluminum-containing conductive layer 150 and a first oxide layer 170. The aluminum-containing conductive layer 150 is disposed within the space 142 and surrounds the first column 140a and the second column 140b, and the first oxide layer 170 is disposed over and conformal to the aluminum-containing conductive layer 150.

In some embodiments, the substrate 110 includes semiconductive material such as silicon, germanium, gallium, arsenic, or a combination thereof. In some embodiments, the substrate 110 is a semiconductor wafer. In some embodiments, the substrate 110 is a silicon substrate. The substrate 110 includes a first surface 110a and a second surface 110b opposite to the first surface 110a. In some embodiments, the first surface 110a is a front side or an active side with several electrical components disposed thereon. In some embodiments, the second surface 110b is a back side or an inactive side from which electrical components are absent. In some embodiments, the substrate 110 includes a commercially available semiconductor wafer that may be diced into semiconductor dies after formation of the first column 140a, the second column 140b, the aluminum-containing conductive layer 150 and the first oxide layer 170. In some embodiments, the substrate 110 has a thickness in a range from 500 to 1,500 μm, although greater or lesser thicknesses may be used.

In some embodiments, the substrate 110 has an active region 112. In some embodiments, the active region 112 includes an isolation structure 114 and a contact 116 adjacent to the isolation structure 114. In some embodiments, the active regions 112 may include silicon. The isolation structure 114 may include oxide, such as silicon oxide or another suitable material. The isolation structure 114 may be a shallow trench isolation (STI) structure. The contact 116 may include a conductive material, such as tungsten (W). In some embodiments, the first column 140a and the second column 140b are disposed on the isolation structure 114. In some embodiments, the active region 112 includes a plurality of isolation structures 114 and a plurality of contacts 116 adjacent to the corresponding isolation structure 114.

In some embodiments, the dielectric stack 120 is disposed on the substrate 110. The dielectric stack 120 includes a first nitride structure 121 over the substrate 110, a first oxide structure 122 over the first nitride structure 121, a second nitride structure 123 over the first oxide structure 122, a second oxide structure 124 over the second nitride structure 123, and a third nitride structure 125 over the second oxide structure 124. In brief, the first nitride structure 121, the first oxide structure 122, the second nitride structure 123, the second oxide structure 124, and the third nitride structure 125 are disposed in sequence over the substrate 110. In some embodiments, the first oxide structure 122 is between the first nitride structure 121 and the second nitride structure 123, and the second oxide structure 124 is between the second nitride structure 123 and the third nitride structure 125. In some embodiments, the first nitride structure 121 is in contact with the isolation structure 114 and the contact 116 of the substrate 110. In some embodiments, a thickness of the first nitride structure 121 is substantially less than a thickness of the first oxide structure 122. In some embodiments, a thickness of the second nitride structure 123 is substantially less than a thickness of the second oxide structure 124. In some embodiments, a thickness of the third nitride structure 125 is substantially less than the thickness of the second oxide structure 124. In some embodiments, the thickness of the third nitride structure 125 is substantially greater than the thickness of the first nitride structure 121 or the thickness of the second nitride structure 123.

In some embodiments, the first nitride structure 121, the second nitride structure 123 and the third nitride structure 125 include same or different materials. In some embodiments, the first nitride structure 121, second nitride structure 123 and the third nitride structure 125 include silicon nitride.

In some embodiments, the first oxide structure 122 and the second oxide structure 124 include same or different materials. In some embodiments, the first oxide structure 122 includes boron (B), phosphorus (P), or a combination thereof. In some embodiments, the first oxide structure 122 includes borophosphosilicate glass (BPSG). In some embodiments, the second oxide structure 124 includes tetraethoxysilane (TEOS) or BPSG.

In some embodiments, the hard mask layer 130 is disposed over the third nitride structure 125. In some embodiments, the hard mask layer 130 includes polysilicon. In some embodiments, a portion of the hard mask layer 130 and a portion of the dielectric stack 120 are removed to form an opening 141 extended through the hard mask layer 130 and the dielectric stack 120, and the corresponding contact 116 of the substrate 110 defines a bottom of the opening 141. In some embodiments, the opening 141 has a lower portion and an upper portion communicating with the lower portion. In some embodiments, the lower portion of the opening 141 is surrounded by the dielectric stack 120 and the upper portion of the opening 141 is surrounded by the hard mask layer 130. In some embodiments, the upper portion of the opening 141 is sealed by the first oxide layer 170, and the space 142 is defined by the first oxide layer 170 and within the opening 141. The space 142 is disposed between the first column 140a and the second column 140b and is surrounded by the first oxide layer 170 located at the lower portion of the opening 141.

In some embodiments, the substrate 110 includes a periphery area 101 and a poly array area 102. In some embodiments, the dielectric stack 120 and the hard mask layer 130 are both disposed in the periphery area 101 and the poly array area 102. At least one opening 141 is formed within the poly array area 102 to define the first column 140a and the second column 140b. In some embodiments, a plurality of openings 141 are formed within the poly array area 102. Each of the openings 141 extends through the hard mask layer 130 and the dielectric stack 120 and divides the dielectric stack 120 and the hard mask layer 130 to form the first column 140a and the second column 140b. In some embodiments, each of the first column 140a and the second column 140b includes the dielectric stack 120 disposed on the active region 112 and the hard mask layer 130 formed on the dielectric stack 120, wherein the second column 140b is disposed adjacent to the first column 140a. In some embodiments, the contact 116 is exposed through the corresponding opening 141. In some embodiments, the openings 141, the isolation structure 114, and the contact 116 are disposed in the poly array area 102.

In some embodiments, a first portion of the hard mask layer 130 is disposed in the periphery area 101, and a second portion of the hard mask layer 130 is disposed in the poly array area 102. In some embodiments, a first thickness T1 of the first portion is substantially greater than or equal to a second thickness T2 of the second portion. In some embodiments, the first thickness T1 is about 100 to 300 nm greater than the second thickness T2.

In some embodiments, the aluminum-containing conductive layer 150 is disposed within the opening 141 and is conformal to the opening 141, and the aluminum-containing conductive layer 150 extends from the opening 141 to cover the hard mask layer 130. In some embodiments, the aluminum-containing conductive layer 150 is continuously disposed over and surrounding the first column 140a and the second column 140b. In some embodiments, the aluminum-containing conductive layer 150 is in contact with and conformal to the first column 140a and the second column 140b. In some embodiments, a portion of the aluminum-containing conductive layer 150 within the opening 141 is in contact with the contact 116. In some embodiments, the aluminum-containing conductive layer 150 is in contact with the contact 116, the dielectric stack 120 and the hard mask layer 130. In some embodiments, within the opening 141, the aluminum-containing conductive layer 150 is surrounded by the hard mask layer 130 and the dielectric stack 120. In some embodiments, the aluminum-containing conductive layer 150 may be referred to as an electrode plate of the capacitor of the semiconductor structure 100, for example, a lower electrode plate.

In some embodiments, the aluminum-containing conductive layer 150 includes aluminum and titanium. In some embodiments, the aluminum-containing conductive layer 150 includes nitride. In some embodiments, the aluminum-containing conductive layer 150 includes TiSiAIN. In some embodiments, the aluminum-containing conductive layer 150 is free of chloride. In some embodiments, a thickness of the aluminum-containing conductive layer 150 is between 5 nm and 15 nm.

In some embodiments, the opening 141 is located between the first column 140a and the second column 140b. In some embodiments, the aluminum-containing conductive layer 150 is continuously formed over the first column 140a and the second column 140b, and the aluminum-containing conductive layer 150 forms a first gap G1, a second gap G2 and a third gap G3 within the opening 141. In some embodiments, the first gap G1, the second gap G2 and the third gap G3 are connected to each other and form a groove, wherein the first gap G1 is surrounded by the hard mask layer 130, the second gap G2 is adjacent to a top surface of the third nitride structure 125, and the third gap G3 is adjacent to a bottom surface of the third nitride structure 125.

In some embodiments, a first width W1 of the first gap G1 is substantially less than a second width W2 of the second gap G2, and the second width W2 of the second gap G2 is substantially less than a third width W3 of the third gap G3.

In some embodiments, the first oxide layer 170 is continuously disposed over and surrounds the aluminum-containing conductive layer 150. In some embodiments, a portion of the first oxide layer 170 is disposed over the aluminum-containing conductive layer 150 and the hard mask layer 130. In some embodiments, a portion of the first oxide layer 170 is disposed within the opening 141 and is surrounded by the aluminum-containing conductive layer 150. In some embodiments, the first oxide layer 170 is formed by atomic layer deposition (ALD).

In some embodiments, the aluminum-containing conductive layer 150 and the first oxide layer 170 are formed on a sidewall of the opening 141. In some embodiments, the upper portion of the opening 141 is sealed by the first oxide layer 170, and a space 142 is defined by the first oxide layer 170 and within the opening 141. The space 142 is disposed between the first column 140a and the second column 140b and is surrounded by the first oxide layer 170 located at the lower portion of the opening 141. As such, after the opening 141 is sealed by the first oxide layer 170, the aluminum-containing conductive layer 150 at the lower portion of the opening 141 is effectively protected by the first oxide layer 170, and impurities such as CMP slurry may not fall into the opening 141.

FIG. 2 is a schematic cross-sectional view of a second semiconductor structure 100b in accordance with some embodiments of the present disclosure. FIG. 3 is an enlarged cross-sectional view of a part of the second semiconductor structure 100b in FIG. 2 in accordance with some embodiments of the present disclosure. The second semiconductor structure 100b illustrated in FIGS. 2 and 3 is similar to the first semiconductor structure 100a illustrated in FIG. 1, except that the second semiconductor structure 100b further includes a second oxide layer 160 disposed between the aluminum-containing conductive layer 150 and the first oxide layer 170. The aluminum-containing conductive layer 150 and the first oxide layer 170 shown in FIGS. 2 and 3 are similar to the aluminum-containing conductive layer 150 and the first oxide layer 170 shown in FIG. 1, and detailed descriptions of such layers are omitted for brevity.

Referring to FIGS. 2 and 3, in some embodiments, a composition of the first oxide layer 170 is different from a composition of the second oxide layer 160. In some embodiments, the second oxide layer 160 is conformal to the aluminum-containing conductive layer 150. In some embodiments, the second oxide layer 160 is continuously formed over the first column 140a and the second column 140b.

In some embodiments, a thickness of the first oxide layer 170 is substantially greater than a thickness of the second oxide layer 160. In some embodiments, a thickness of the aluminum-containing conductive layer 150 is substantially greater than the thickness of the second oxide layer 160. In some embodiments, the second oxide layer 160 includes oxidized aluminum-containing conductive material of the aluminum-containing conductive layer 150. In some embodiments, the second oxide layer 160 includes oxidized TiN, oxidized TiSiN, or the like.

FIG. 4 is a flow diagram illustrating a method 400 of manufacturing the first semiconductor structure 100a and/or the second semiconductor structure 100b in accordance with some embodiments of the present disclosure, and FIGS. 5 to 19 illustrate cross-sectional views or schematic views of intermediate stages in the formation of the first semiconductor structure 100a and/or the second semiconductor structure 100b in accordance with some embodiments of the present disclosure.

The stages shown in FIGS. 5 to 19 are also illustrated schematically in the flow diagram in FIG. 4. In the following description, the fabrication stages shown in FIGS. 5 to 19 are discussed in reference to the process steps shown in FIG. 4. The method 400 includes a number of operations and the description and illustration are not deemed as a limitation to the sequence of the operations. The method 400 includes a number of steps (401, 402, 403, 404, 405, 406, and 407).

The method 400 begins with operation 401. Operation 401 includes providing a substrate having an active region, wherein the active region includes an isolation structure and a contact adjacent to the isolation structure. In some embodiments, a substrate 110 having an active region 112 is provided, wherein the active region 112 includes an isolation structure 114 and a contact 116 adjacent to the isolation structure 114 as shown in FIG. 5. In some embodiments, the substrate 110 includes a periphery area 101 and a poly array area 102.

In some embodiments, the substrate 110 is a semiconductive layer. In some embodiments, the substrate 110 includes semiconductive material. In some embodiments, the substrate 110 is a silicon substrate. In some embodiments, the active region 112 includes silicon. In some embodiments, the isolation structure 114 is made of oxide, such as silicon oxide or another suitable material. The isolation structure 114 may be a shallow trench isolation (STI) structure. In some embodiments, the contact 116 is made of a conductive material, such as tungsten (W).

The method 400 continues with operation 402. Operation 402 includes forming a dielectric stack on the substrate. In operation 402, referring to FIG. 5, a dielectric stack 120 is formed on the substrate 110. In some embodiments, the dielectric stack 120 is formed on both the periphery area 101 and the poly array area 102 of the substrate 110.

In some embodiments, a first nitride structure 121 is formed over the substrate 110, a first oxide structure 122 is formed over the first nitride structure 121, a second nitride structure 123 is formed over the first oxide structure 122, a second oxide structure 124 is formed over the second nitride structure 123, and a third nitride structure 125 is formed over the second oxide structure 124. In some embodiments, the first nitride structure 121 is in contact with the isolation structure 114 and the contact 116 of the substrate 110.

In some embodiments, the first nitride structure 121, the first oxide structure 122, the second nitride structure 123, the second oxide structure 124, and the third nitride structure 125 are formed in sequence. In some embodiments, each of the first nitride structure 121, the first oxide structure 122, the second nitride structure 123, the second oxide structure 124, and the third nitride structure 125 may be formed, for example, by any acceptable deposition process, such as spin coating, chemical vapor deposition (CVD), atomic layer deposition (ALD), physical vapor deposition (PVD), laminating, the like, or a combination thereof.

In some embodiments, the first nitride structure 121, the second nitride structure 123, and the third nitride structure 125 include silicon nitride. In some embodiments, the first oxide structure 122 includes BPSG, and the second oxide structure 124 includes TEOS.

The method 400 continues with operation 403. Operation 403 includes forming a hard mask layer on the dielectric stack. In operation 403, referring to FIG. 5, a hard mask layer 130 is formed on the dielectric stack 120. In some embodiments, the hard mask layer 130 is formed on both the periphery area 101 and the poly array area 102 of the substrate 110. In some embodiments, the hard mask layer 130 may be formed, for example, by any acceptable deposition process, such as spin coating, chemical vapor deposition (CVD), atomic layer deposition (ALD), physical vapor deposition (PVD), laminating, the like, or a combination thereof.

The method 400 continues with operation 404. Operation 404 includes etching the hard mask layer and the dielectric stack to form an opening to expose the contact of the substrate. In operation 404, referring to FIG. 5, the hard mask layer 130 and the dielectric stack 120 are etched to form an opening 141 to expose the contact 116 of the substrate 110. In some embodiments, a plurality of openings 141 through the hard mask layer 130 and the dielectric stack 120 are formed by a patterning operation to expose a plurality of contacts 116.

In some embodiments, only the hard mask layer 130 and the dielectric stack 120 in the poly array area 102 of the substrate 110 are patterned/etched, and the opening 141 is formed within the poly array area 102. In some embodiments, after the etching, a first column 140a and a second column 140b are formed within the poly array area 102. In some embodiments, after the etching, a first portion of the hard mask layer 130 disposed in the periphery area 101 is thicker than a second portion of the hard mask layer 130 disposed in the poly array area 102. In some embodiments, a first thickness T1 of the first portion is substantially greater than a second thickness T2 of the second portion.

In some embodiments, portions of the hard mask layer 130 and the dielectric stack 120 are removed by the etching operation or the patterning operation to form the openings 141. The etching operation or the patterning operation includes a plasma etching process, a wet etching process, a dry etching process, and/or another type of etch technique. In some embodiments, portions of the hard mask layer 130 and the dielectric stack 120 are removed by a dry etching process. In some embodiments, a dry etchant, such as hydrogen (H₂) or nitrogen (N₂), may be used in the dry etching process.

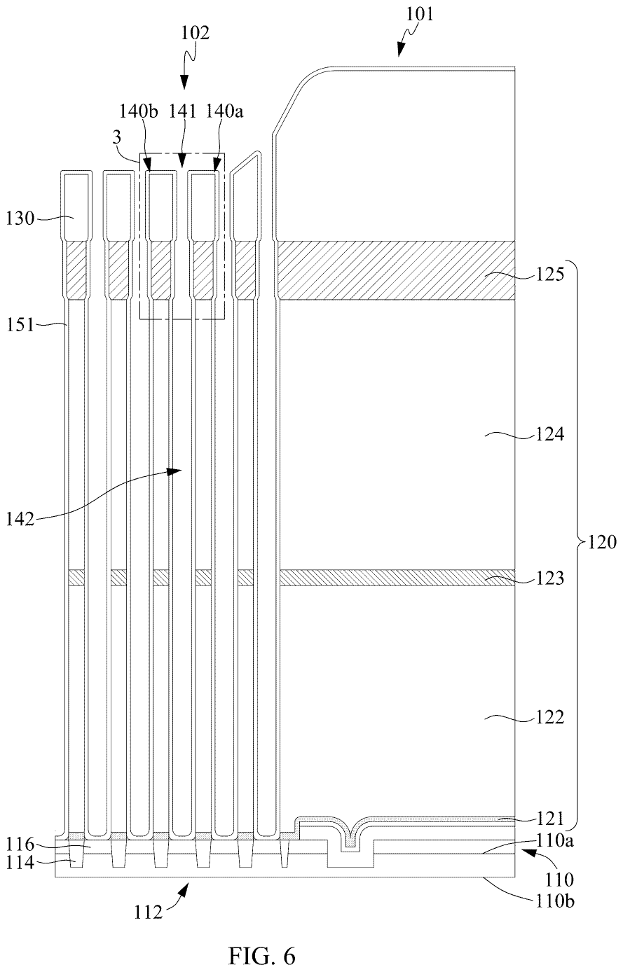

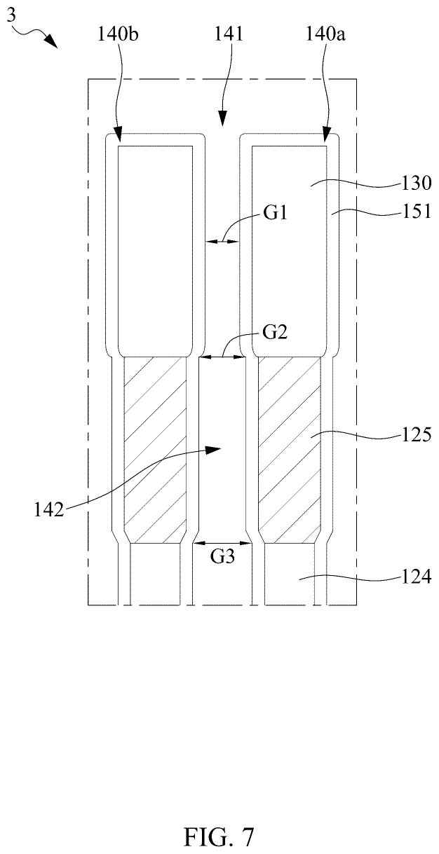

The method 400 continues with operation 405. Operation 405 includes forming a conductive film within the opening and over the hard mask layer, wherein the conductive film is conformal to the opening. In operation 405, referring to FIGS. 6 and 7, a conductive film 151 is formed within the opening 141 and over the hard mask layer 130, wherein the conductive film 151 is conformal to the opening 141 and extends from the opening 141 to cover the hard mask layer 130. The conductive film 151 surrounds the first column 140a and the second column 140b. In some embodiments, the conductive film 151 is continuously disposed over and surrounds the first column 140a and the second column 140b. In some embodiments, the conductive film 151 is in contact with and conformal to the first column 140a and the second column 140b. In some embodiments, a portion of the conductive film 151 within the opening 141 is in contact with the contact 116. In some embodiments, the conductive film 151 is in contact with the contact 116, the dielectric stack 120 and the hard mask layer 130. In some embodiments, within the opening 141, the conductive film 151 is surrounded by the hard mask layer 130 and the dielectric stack 120.

In some embodiments, the opening 141 is located between the first column 140a and the second column 140b. In some embodiments, the conductive film 151 is continuously formed over the first column 140a and the second column 140b, and the conductive film 151 forms a first gap G1, a second gap G2 and a third gap G3. In some embodiments, the first gap G1, the second gap G2 and the third gap G3 are connected to each other and form a groove, wherein the first gap G1 is surrounded by the hard mask layer 130, the second gap G2 is adjacent to a top surface of the third nitride structure 125, and the third gap G3 is adjacent to a bottom surface of the third nitride structure 125. In some embodiments, a first width W1 of the first gap G1 is substantially less than a second width W2 of the second gap G2, and the second width W2 of the second gap G2 is substantially less than a third width W3 of the third gap G3.

The method 400 continues with operation 406. Operation 406 includes modifying the conductive film, to turn the conductive film into an aluminum-containing conductive layer. In operation 406, referring to FIGS. 8 to 10, the conductive film 151 is modified to turn the conductive film 151 into an aluminum-containing conductive layer 150. In some embodiments, operation 406 includes aluminating the conductive film 151 to incorporate aluminum into the conductive film 151. In some embodiments, the aluminum-containing conductive layer 150 has better antioxidant capacity than the conductive film 151, and is not easily damaged in subsequent processes.

In some embodiments, operation 406 includes providing aluminum and/or aluminum-containing fluoride 152 to contact the conductive film 151, and heating the aluminum and/or aluminum-containing fluoride 152 and the conductive film 151 to form the aluminum-containing conductive layer 150. In some embodiments, the heating performed on the aluminum and/or aluminum-containing fluoride 152 and the conductive film 151 is thermal heating. In some embodiments, the aluminum and/or aluminum-containing fluoride 152 is in a form of particles.

In some embodiments, a temperature for the heating performed on the aluminum and/or aluminum-containing fluoride 152 and the conductive film 151 is between 650° C. and 900° C., preferably between 700° C. and 800° C. In some embodiments, a duration for the heating performed on the aluminum and/or aluminum-containing fluoride 152 and the conductive film 151 is less than 15 seconds, preferably between 5 and 10 seconds. In some embodiments, the aluminum and/or aluminum-containing fluoride 152 and the conductive film 151 are disposed in a reaction chamber and an argon (Ar) gas environment is provided within the reaction chamber during the heating.

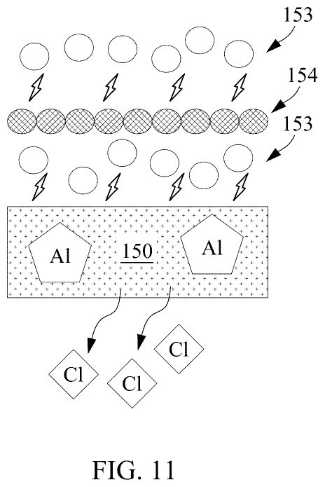

In some embodiments, the conductive film 151 includes chloride. In some embodiments, some chloride is introduced into the conductive film 151 during the formation of the aluminum-containing conductive layer 150. In some embodiments, referring to FIG. 11, after the aluminum-containing conductive layer 150 is formed, the method 400 further includes removing the chloride from the aluminum-containing conductive layer 150.

In some embodiments, removal of the chloride from the aluminum-containing conductive layer 150 includes providing nitrogen plasma 153 to contact the aluminum-containing conductive layer 150, and providing a precursor 154 to contact the aluminum-containing conductive layer 150. In some embodiments, the aluminum-containing conductive layer 150 undergoes a reduction reaction upon contact with the nitrogen plasma 153. In some embodiments, the precursor 154 includes carbon-containing precursors, nitrogen-containing precursor, silicon-containing precursor or a combination thereof. In some embodiments, the silicon-containing precursor includes aminosilane, silicate, halosilane, or a combination thereof. Examples of aminosilane include bis(diethylamino) silane (BDEAS), bis(dimethylamino) silane (BDMAS), Tris(dimethylamino) silane (TDMAS), Bis(tert-butylamino) silane, (BTBAS), bis(dimethylamino) dimethyl silane, hexakisethylaminodisilane, tetrapropylsilanetetramine, 3-aminopropyltriethoxysilane, and combinations thereof. Examples of silicate include trimethylsilane, dimethylsilyloxy (dimethyl) silane, methyltrimethoxysiloxane, tetramethylsilane, hexamethyldisiloxane, tetraethyl orthosilicate, tetrapropyl orthosilicate, and combinations thereof. Examples of halosilane includes SiBr₄, SiCl₄, and combinations thereof.

In some embodiments, the two steps of providing nitrogen plasma 153 and providing precursors 154 are performed multiple times in sequence in order to remove as much chlorine as possible.

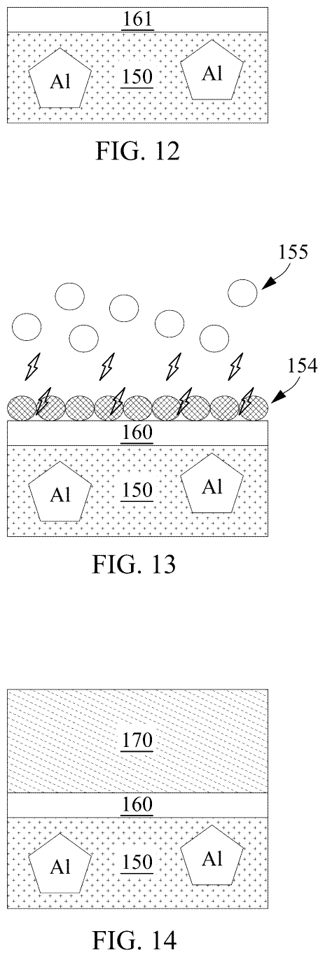

In some embodiments, referring to FIG. 12, the method 400 further includes forming a barrier layer 161 over the aluminum-containing conductive layer 150. In some embodiments, the barrier layer 161 is formed due to the reduction reaction of the aluminum-containing conductive layer 150 and the nitrogen plasma 153. In some embodiments, the barrier layer 161 includes silicon nitride oxide (SiON). In some embodiments, a thickness of the aluminum-containing conductive layer 150 is between 5 nm to 15 nm, and a thickness of the barrier layer 161 is less than the thickness of the aluminum-containing conductive layer 150. In some embodiments, the thickness of the barrier layer 161 is less than 5 nm. In some embodiments, the aluminum-containing conductive layer 150 is free of chloride when the barrier layer 161 is formed.

The method 400 continues with operation 407. Operation 407 includes depositing a first oxide layer over the aluminum-containing conductive layer, wherein the first oxide layer is conformal to the aluminum-containing conductive layer. In operation 407, referring to FIGS. 13 to 15, a first oxide layer 170 is deposited over the aluminum-containing conductive layer 150, wherein the first oxide layer 170 is conformal to the aluminum-containing conductive layer 150. In some embodiments, the first oxide layer 170 is formed over the barrier layer 161 by atomic layer deposition (ALD). In some embodiments, the first oxide layer 170 includes silicon dioxide.

In some embodiments, the atomic layer deposition (ALD) process includes introducing two different chemical precursors into the reaction chamber at different times to form two half-cycle reactions. The reactions are limited to the surface through surface chemical adsorption, and therefore a thin film of an atomic layer can be deposited. Further, these two half-cycle reactions may be repeated sequentially and continuously, and the thin film can be grown layer by layer. Depositing thin films through two half-cycle reactions can avoid the simultaneous presence of two chemical precursors in the reaction chamber, so the atomic layer deposition process can accurately control the thickness and uniformity of the film. In some embodiments, the precursors of the atomic layer deposition process include silicon-containing precursors and oxygen-containing precursors. In some embodiments, the silicon-containing precursor includes aminosilane, silicate, halosilane, or a combination thereof.

In some embodiments, a feed rate of the silicon-containing precursor is 1.0 L/min to 2.0 L/min. In some embodiments, the oxygen-containing precursor includes oxygen, ozone, water, carbon monoxide, carbon dioxide, nitric oxide, nitrogen dioxide, or a combination thereof. In some embodiments, the oxygen-containing precursor is oxygen, and the feed rate is 0.5 L/min to 1.5 L/min. In some embodiments, a pressure of the atomic layer deposition process is less than 10 Torr. In some embodiments, the pressure of the atomic layer deposition process is between 1.5 Torr and 8.5 Torr. When the pressure of the atomic layer deposition process is less than 1.5 Torr, each cycle takes a long time and a deposition rate is not fast enough; when the pressure of the atomic layer deposition process is greater than 10 Torr, a residence time of the precursor in the reaction chamber may be too short. In some embodiments, a temperature of the atomic layer deposition process is between 35° C. and 250° C. When the temperature of the atomic layer deposition process is less than 35° C., a thermal energy may not be enough to cause a reaction between the precursors; when the temperature of the atomic layer deposition process is greater than 250° C., the reaction rate may be too fast, reducing a density and uniformity of the film. A power for the ALD process is not less than 1000 W.

In some embodiments, the barrier layer 161 is oxidized into a second oxide layer 160 during the formation of the first oxide layer 170. In some embodiments, the second oxide layer 160 includes oxidized TiSiN. In some embodiments, the first oxide layer 170 is continuously disposed over and surrounds the second oxide layer 160, and the second oxide layer 160 is formed between the first oxide layer 170 and the aluminum-containing conductive layer 150. In some embodiments, a portion of the first oxide layer 170 is disposed within the opening 141 and is surrounded by the second oxide layer 160.

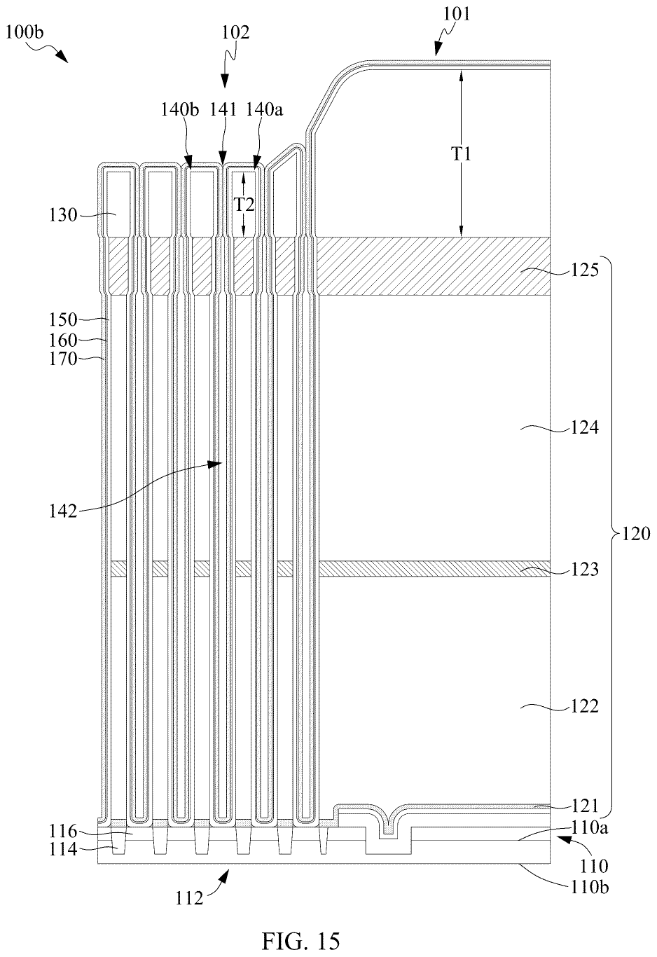

In some embodiments, referring to FIG. 15, the opening 141 is sealed by the first oxide layer 170, wherein the first oxide layer 170 covers an upper portion of the opening 141 and a space 142 is defined by the first oxide layer 170. The space 142 is surrounded by the first oxide layer 170 located at a lower portion of the opening 141, and the space 142 is also surrounded by the dielectric stack 120. As such, after the opening 141 is sealed by the first oxide layer 170, the aluminum-containing conductive layer 150 at the lower portion of the opening 141 is effectively protected by the first oxide layer 170, as a result, impurities such as CMP slurry may not fall into the opening 141 and the space 142.

In some embodiments, as shown in FIG. 15, the hard mask layer 130 includes the first portion and the second portion. At this stage, both of the first portion and the second portion of the hard mask layer 130 are disposed under and surrounded by a stack including the aluminum-containing conductive layer 150, the first oxide layer 170 and the second oxide layer 160. The first oxide layer 170 is formed to protect the aluminum-containing conductive layer 150 by reducing a diameter of the opening 141, so that tiny particles easily generated by subsequent processes, such as a chemical mechanical planarization process, are less likely to fall into the opening 141, thereby avoiding damage to the aluminum-containing conductive layer 150 in the subsequent processes. In some embodiments, a second semiconductor structure 100b is formed.

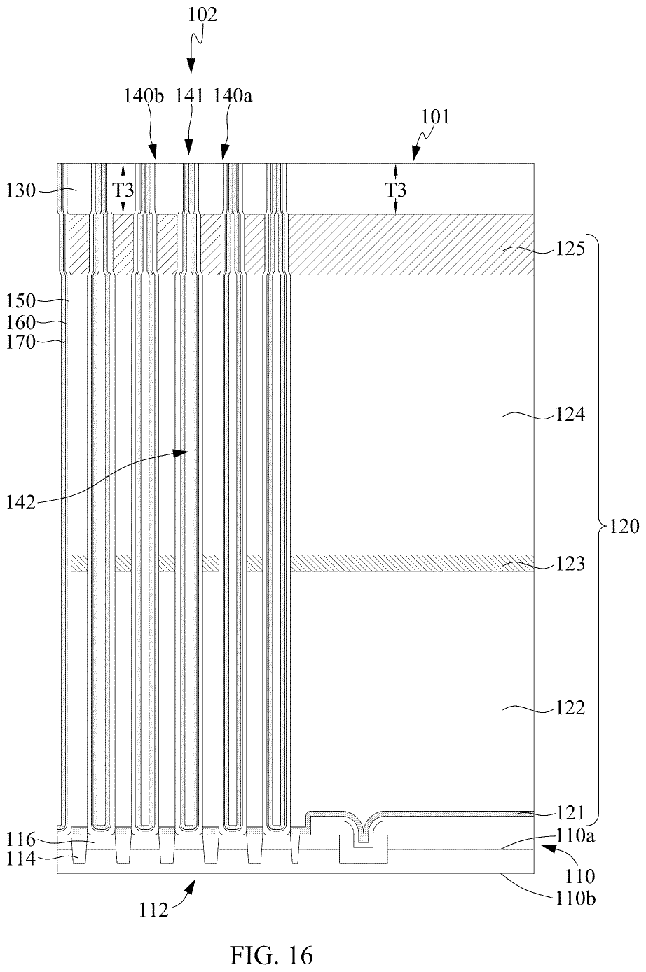

The method 400 further includes removing a portion of the first oxide layer 170, a portion of the second oxide layer 160, a portion of the aluminum-containing conductive layer 150 and a portion of the hard mask layer 130 in the active area 102 to open the space 142. In some embodiments, referring to FIG. 16, a planarization process is performed on the second semiconductor structure 100b, wherein a portion of the second semiconductor structure 100b is removed. In some embodiments, the planarization process is a chemical-mechanical polishing (CMP) process, which includes providing a slurry to the second semiconductor structure 100b to remove a portion of the first oxide layer 170, a portion of the second oxide layer 160 and a portion of the aluminum-containing conductive layer 150 disposed over the hard mask layer 130. In some embodiments, the hard mask layer 130 is polished about 300 to 400 nm at the periphery area 101 and about 100 to 200 nm at the poly array area 102. In some embodiments, after the polishing, the hard mask layer 130 disposed in the periphery area 101 and the poly array area 102 has a uniform thickness T3. Due to the opening 141 being sealed by the first oxide layer 170, the slurry used in the CMP process and the tiny particles generated during the CMP process are prevented from entering the space 142.

In the above step, an in-situ rate monitor (ISRM) is used to monitor an end point of the grinding (EPD). The polishing rate monitor monitors a rate of the CMP and detects a surface between the third nitride structure 125 and the hard mask layer 130 to determine when to stop the CMP process.

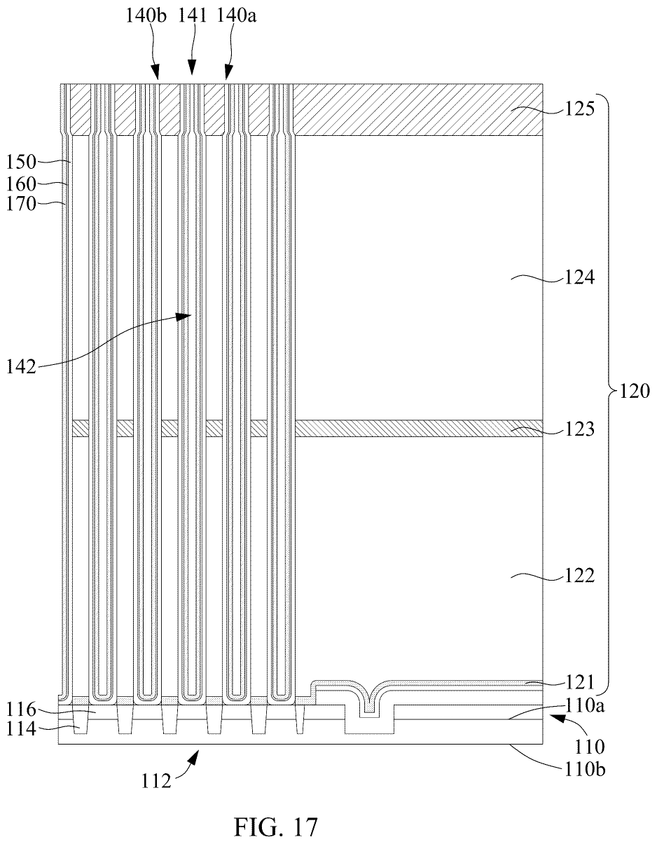

In some embodiments, referring to FIG. 17, after the CMP process, the remaining hard mask layer 130 is further removed and the opening 141 is reopened. After the removal of the remaining hard mask layer 130, the third nitride structure 125 is exposed in the periphery area 101 and the poly array area 102.

In some embodiments, the remaining hard mask layer 130 is removed by a wet etching process, and the first oxide layer 170, the second oxide layer 160 and the aluminum-containing conductive layer 150 surrounding the hard mask layer 130 may also be removed. An etchant used in the wet etching process may include sulfuric acid (H₂SO₄), hydrogen peroxide (H₂O₂), hydrofluoric acid (HF), ammonium hydroxide (NH₄OH), or a combination thereof.

In some embodiments, the remaining hard mask layer 130 is removed by a dry etching process, and the first oxide layer 170, the second oxide layer 160 and the aluminum-containing conductive layer 150 surrounding the hard mask layer 130 may also be removed. An etchant used in the dry etching process may include boron trichloride (BCl₃), chlorine (Cl₂), or a combination thereof.

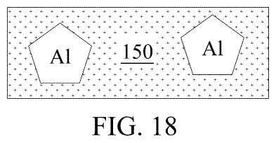

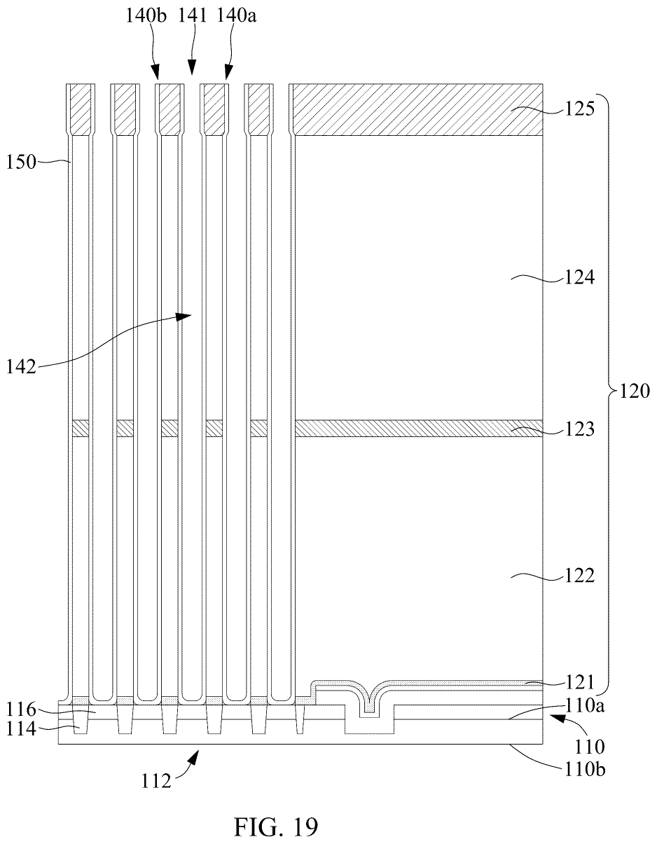

In some embodiments, referring to FIGS. 18 to 19, the method further includes removing the first oxide layer 170 and the second oxide layer 160 from the space 142. In some embodiments, the first oxide layer 170 and the second oxide layer 160 are removed from the opening 141. In some embodiments, a portion of the first oxide layer 170 within the space 142 is removed, and the aluminum-containing conductive layer 150 is exposed after the removal of the first oxide layer 170. In some embodiments, a portion of the second oxide layer 160 within the space 142 is removed after the removal of the first oxide layer 170. In some embodiments, since the aluminum-containing conductive layer 150 includes aluminum, it may remain undamaged during the removal of the first oxide layer 170 and the second oxide layer 160. In some embodiments, a thickness of the aluminum-containing conductive layer 150 remains the same before and after the removal the first oxide layer 170 and the second oxide layer 160 from the space 142. In some embodiments, a difference between the thicknesses of the aluminum-containing conductive layer 150 before and after the removal the first oxide layer 170 and the second oxide layer 160 from the space 142 is less than 1 nm, preferably less than 10 Å.

In conclusion, a semiconductor structure 100a, 100b of the present disclosure includes a first oxide layer 170 configured to seal an opening 141 during a CMP process, and an aluminum-containing conductive layer 150 not easily damaged during a subsequent process of removing the first oxide layer 170. As a result, favorable electrical performance and reliability of the semiconductor structure are guaranteed.

One aspect of the present disclosure provides a semiconductor structure. The semiconductor structure includes a substrate, a dielectric stack disposed on the substrate, and a hard mask layer disposed on the dielectric stack. The semiconductor structure further includes an aluminum-containing conductive layer surrounding the hard mask layer and the dielectric stack and over the hard mask layer from a cross-section view, wherein the aluminum-containing conductive layer is conformal to the hard mask layer and the dielectric stack; and a first oxide layer disposed over and conformal to the aluminum-containing conductive layer.

Another aspect of the present disclosure provides a semiconductor structure. The semiconductor structure includes a substrate having an active region, a first column disposed on the active region, a second column disposed on the active region and adjacent to the first column, and an aluminum-containing conductive layer continuously disposed over and surrounding the first column and the second column. The aluminum-containing conductive layer is conformal to the first column and the second column.

Another aspect of the present disclosure provides a method of manufacturing a semiconductor structure. The method includes steps of providing a substrate having an active region, wherein the active region includes an isolation structure and a contact adjacent to the isolation structure; forming a dielectric stack on the substrate; forming a hard mask layer on the dielectric stack; and etching the hard mask layer and the dielectric stack to form an opening to expose the contact of the substrate. The method further includes steps of forming a conductive film within the opening and over the hard mask layer, wherein the conductive film is conformal to the opening; modifying the conductive film to turn the conductive film into an aluminum-containing conductive layer; and depositing a first oxide layer over the aluminum-containing conductive layer, wherein the first oxide layer is conformal to the aluminum-containing conductive layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A method of manufacturing a semiconductor structure, comprising:
providing a substrate having an active region, wherein the active region includes an isolation structure and a contact adjacent to the isolation structure;
forming a dielectric stack on the substrate;
forming a hard mask layer on the dielectric stack;
etching the hard mask layer and the dielectric stack to form an opening to expose the contact of the substrate;
forming a conductive film within the opening and over the hard mask layer, wherein the conductive film is conformal to the opening;
modifying the conductive film to turn the conductive film into an aluminum-containing conductive layer; and
depositing a first oxide layer over the aluminum-containing conductive layer, wherein the first oxide layer is conformal to the aluminum-containing conductive layer.

2. The method of claim 1, further comprising:
sealing the opening with the first oxide layer,
wherein after the opening is sealed by the first oxide layer, the first oxide layer defines a space surrounded by the dielectric stack.

3. The method of claim 2, further comprising:
removing a portion of the first oxide layer, a portion of the aluminum-containing conductive layer and a portion of the hard mask layer in the active area to open the space; and
removing a portion of the first oxide layer within the space.

4. The method of claim 1, wherein the modification of the conductive film includes:
providing aluminum-containing fluoride to contact the conductive film; and
heating the aluminum-containing fluoride and the conductive film to form the aluminum-containing conductive layer.

5. The method of claim 4, wherein a duration of the heating is less than 15 seconds.

6. The method of claim 4, wherein a temperature of the heating is between 650° C. and 900° C.

7. The method of claim 1, further comprising:
removing chloride from the aluminum-containing conductive layer.

8. The method of claim 7, wherein the removal of the chloride from the aluminum-containing conductive layer includes:
providing nitrogen plasma to contact the aluminum-containing conductive layer; and
providing a precursor to contact the aluminum-containing conductive layer.

9. The method of claim 1, further comprising:
forming a barrier layer over the aluminum-containing conductive layer before the formation of the first oxide layer; and
oxidizing the barrier layer into a second oxide layer during the formation of the first oxide layer.

10. The method of claim 1, wherein the second oxide layer is disposed between the first oxide layer and the aluminum-containing conductive layer.

11. The method of claim 1, wherein the first oxide layer is formed over the barrier layer by atomic layer deposition.

12. The method of claim 1, wherein the barrier layer includes SiON.

13. The method of claim 1, wherein a thickness of the barrier layer is less than 5 nm.

14. The method of claim 1, further comprising:
sealing the opening with the first oxide layer, wherein after the opening is sealed by the first oxide layer, the first oxide layer defines a space surrounded by the dielectric stack;
removing a portion of the first oxide layer, a portion of the second oxide layer, a portion of the aluminum-containing conductive layer and a portion of the hard mask layer in the active area to open the space; and
removing the first oxide layer and the second oxide layer from the space.
